(19) United States
(12) Patent Application Publication
(10) Pub. No.: US 2005/0086800 A1
(43) Pub. Date: Apr. 28, 2005

(54) Method for improved traceability of components used in manufacturing of a printed circuit board (PCB)

(76) Inventor: Jeffrey Heidel, Newton, KS (US)

Correspondence Address: LSI LOGIC CORPORATION, 1621 BARBER LANE, MS: D-106, MILPITAS, CA, 95035, US

(21) Appl. No.: 10/695,880

(22) Filed: Oct. 28, 2003

(51) Int. Cl. H05K 3/30; B23P 19/00; G05F 1/00

(52) U.S. Cl. 29/832; 29/739; 29/593

(57) ABSTRACT

A method and apparatus correlate information about a component to be placed on a circuit board with information about the circuit board. This correlated information is placed in a database. A report is generated from the database contents and sent to an end user. The information about the component may be provided by a carrier or tube that contains the component and is loaded into a placement machine for populating the circuit board.

### FIELD OF THE INVENTION

The present invention generally relates to the field of populating printed circuit boards, and particularly to methods for providing traceable records regarding the populating of printed circuit boards.

### BACKGROUND OF THE INVENTION

As the size of the components on printed circuit boards (PCBs) decreases, it is becoming impossible for the manufacturers of these components to mark them with any kind of meaningful information. The lack of information regarding components on a printed circuit board becomes significant for an end user when trying to determine the correct placement of a component on a PCB or the specific date code of the components populated. Currently, amongst contract manufacturers (CM), there is no method to automatically provide a report to the end user that shows the suppliers, supplier part numbers, and date codes associated with the components on a PCB, the PCB itself, or the date of assembly of the fully populated PCB. Current techniques only permit a Contract Manufacturer to list components that were in stock at the time the PCB is populated. There is no reporting capability that provides meaningful information, resulting in a lack of determinability as to the identity of a supplier or a specific date when there are multiple suppliers and/or date codes. Usually this situation is of little consequence; however, if a supplier were to recall a particular component by part number or date code, recalling the specific PCBs that were populated with the component in question would not be doable.

Therefore, it is desirable to provide a method and apparatus for identifying components populated on each printed circuit board and to provide this information to an end user.

### SUMMARY OF THE INVENTION

Accordingly, the present invention is directed to a method and apparatus for identifying component carriers and printed circuit boards, storing the scanned information into a database, and generating a report to facilitate tracing problematic or faulty circuit boards.

In a first aspect of the present invention, a database associated with a component placement machine to populate printed circuit boards is created at the site of a contract manufacturer. This database may later be provided to the end user that has contracted with the contract manufacturer. The basic process may be performed according to the following steps. The contract manufacturer receives components required to populate a printed circuit board. A bar code or other readable indicia is added to the component carrier that holds the components. The barcode may include the customer part number, the contract manufacturer's part number, the manufacturer's name, the manufacturer's part number, and the date code of the component. When the placement machine is set up to populate a printed circuit board, the operator scans each component carrier (e.g., tube, tray, or reel and tape) before loading it into the placement machine. The information from this scan is used to verify the proper component is loaded. The operator (or end user) may be alerted if the wrong part number is being used. As the unpopulated printed circuit board is loaded into the placement machine, the placement machine scans the printed circuit board number and tracer number and records this information in the database. As each component is being populated on the printed circuit board, the customer part number, the contract manufacturer part number, the manufacturer's name, the manufacturer's part number, and the date code of the component are recorded in the database. The contract manufacturer provides the data back to the customer; preferably, as a report.

The present invention facilitates locating with precision printed circuit boards that contains questionable or faulty components, providing a more effective tool to notify customers of a potential recall or other advisement. That is, printed circuit boards with components that are being recalled or that may have potential problems may be quickly identified by searching the database and generating a list of the affected printed circuit board part numbers and their corresponding tracer numbers. Additionally, since the method of the present invention creates a database that tracks the manufacturer's name and part numbers, the database may be used to track purchasing trends. For example, if it is learned that a significant percentage of purchases of a component are from a supplier, the data may be used to negotiate better pricing from the supplier through a large volume discount.

It is to be understood that both the forgoing general description and the following detailed description are exemplary and explanatory only and are not restrictive of the invention as claimed. The accompanying drawings, which are incorporated in and constitute a part of the specification, illustrate an embodiment of the invention and together with the general description, serve to explain the principles of the invention.

### BRIEF DESCRIPTION OF THE DRAWINGS

The numerous advantages of the present invention may be better understood by those skilled in the art by reference to the accompanying figures in which:

FIG. 1 illustrates an embodiment of the method for tracking components of the present invention;

FIG. 2 illustrates an embodiment of a method for creating a tube or carrier of components for use in populating a printed circuit board in the present invention;

FIG. 3 illustrates an embodiment of a method for loading a placement machine in the present invention;

FIG. 4 illustrates an embodiment of a method for placing components on a printed circuit board and generating a database in the present invention;

FIG. 5 illustrates an embodiment of a method of populating a printed circuit board in which replacement components may be used on the fly;

FIG. 6 illustrates an embodiment of a method of populating multiple printed circuit boards using one component carrier or tube;

FIG. 7 illustrates an example of a report of the present invention;

FIG. 8 illustrates an embodiment of an apparatus of the present invention permitting manual scanning;

FIG. 9 illustrates an embodiment of an apparatus of the present invention using automatic placement;

FIG. 10 illustrates an embodiment of the placement machine with load slots for the component carriers in the present invention;

FIG. 11 illustrates a block diagram of an embodiment of a processing system within or associated with the placement machine; and

FIG. 12 illustrates an embodiment of a method of scanning a printed circuit board in the present invention.

### DETAILED DESCRIPTION OF THE INVENTION

Reference will now be made in detail to the presently preferred embodiments of the invention, examples of which are illustrated in the accompanying drawings.

The present invention relates to a method and apparatus for tracing components and circuit boards which are assembled into a finished product. In a preferred embodiment, a bar code is affixed to a component carrier or tube. The circuit board also includes a bar code. A bar code reader or scanner on or coupled to a placement machine extracts information about the component carrier and the circuit board. This information is stored in a database on site at the contract manufacturer's location. A report may later or simultaneously be generated from the database and sent to an end user. The database itself may later be provided to the end user that has contracted with the contract manufacturer. The information stored in the database may include the printed circuit board number, the printed circuit board tracer number, the customer's part number, the contract manufacturer's part number, the manufacturer's name, the manufacturer's part number, and the date code of the component. The operator (or end user) may be alerted if the wrong part number is being used. The alert may be audible as through a buzzer or visual as through a flashing light emitting diodes or a display prompt on a graphical user interface. The alert state may also be used to stop population operations by the placement machine.

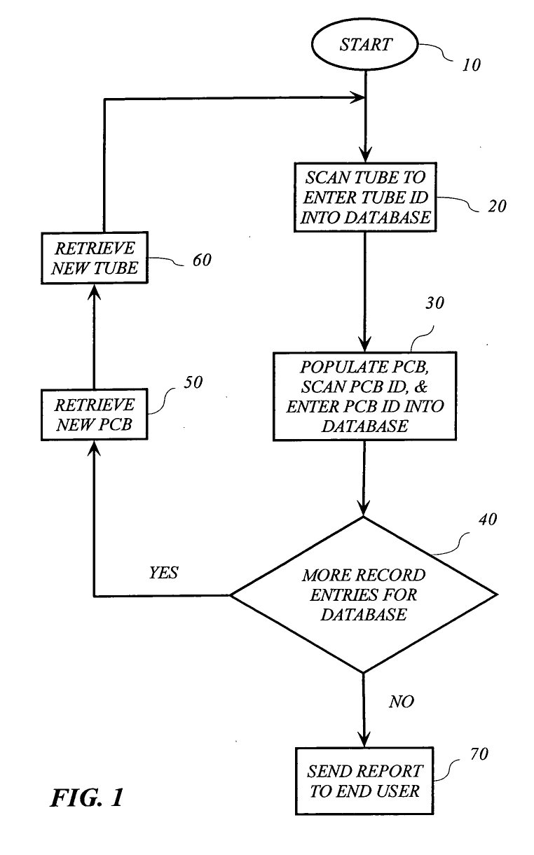

The present invention, in a first embodiment, relates to a method for providing a traceable populated printed circuit board, as illustrated in FIG. 1. A tube is loaded into a placement machine. Before, during, or after placement of the tube (or, component carrier) in the placement machine, the tube is scanned to provide identification information and other information 20. A component carrier is a closed or partially opened housing that is used to transport components and, optionally, arrange them for automatic retrieval and manipulation by the placement machine. A component is a discrete element that is placed on the printed circuit board, such as a capacitor, resistor, transistor, diode, or integrated circuit chip. A tube is a form of component carrier that may be an elongated plastic cylinder with an internal structure to permit the arrangement of components in a uniform and organized manner. Alternately, a component carrier may be a tray, a tape and reel, or the like. An integrated circuit dual-in-line-package may slide onto a ridge like structure inside the body of the tube in tandem with other integrated circuit dual-in-line-package. Additionally or alternatively, the tube may contain barcoded components. The printed circuit board may be held by suction to a flat plate and manipulated three dimensionally by a mechanical apparatus that is part of the placement machine. Identification information for the printed circuit board may be etched into the circuit board substrate, adhesively applied, screen printed, or provided in another manner; however, barcoding is preferably used. The printed circuit board is controlled and manipulated by the placement machine is populated 30. In an embodiment, the printed circuit board identification information is retrieved from the 30 barcode reading by a scanner. The identification information may be read by other methods such as the use of radio frequency communications (e.g., RF ID) or electronic addressing (e.g., through the use of dual-in-line-process or DIP switches). The identification information and other information are entered into a database by a processor coupled to the placement machine 30. Preferably, the processor is contained within or on the placement machine, rather than at a remote location, to improve access by troubleshooting personnel. A determination is made as to whether there are more record entries for the database 40. In other words, the processor determines if there are more printed circuit boards scheduled to be populated and, perhaps, if there are sufficient component resources for the population. If there are more printed circuit boards to populate and sufficient resources to do so, then a new printed circuit board is retrieved 50 and a new tube is retrieved 60. Otherwise, processing stops and a report is provided to an end user 70 The report may be displayed on a screen on or coupled to the placement machine, may be printed out, or may be transmitted locally or remotely, such as via the world wide web.

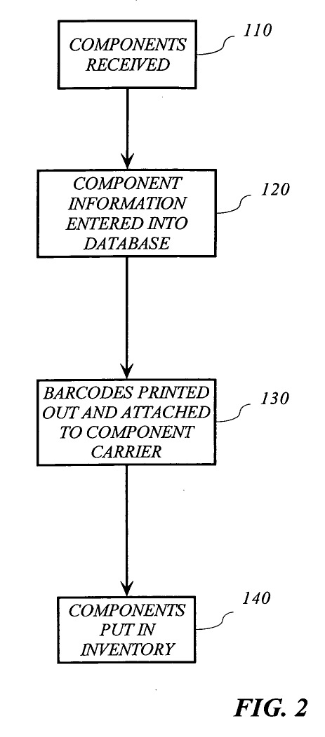

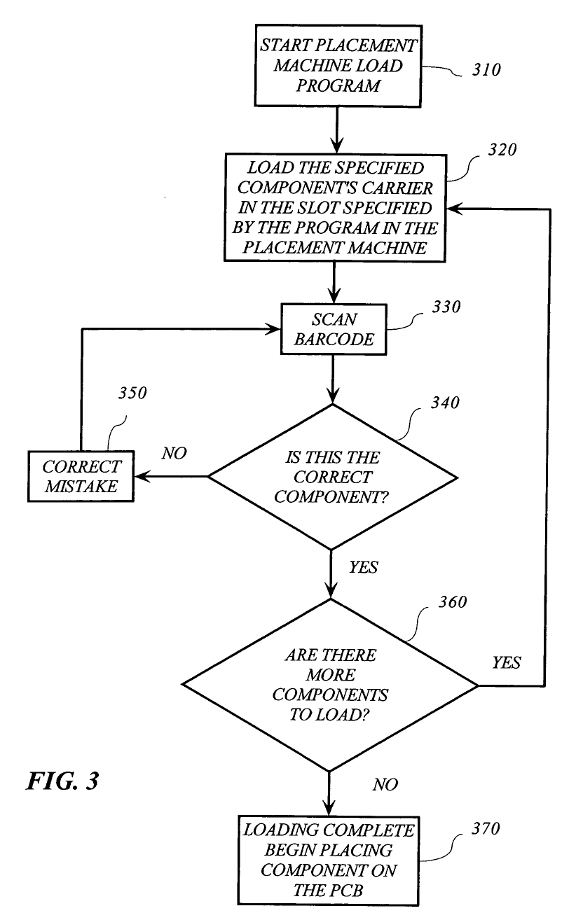

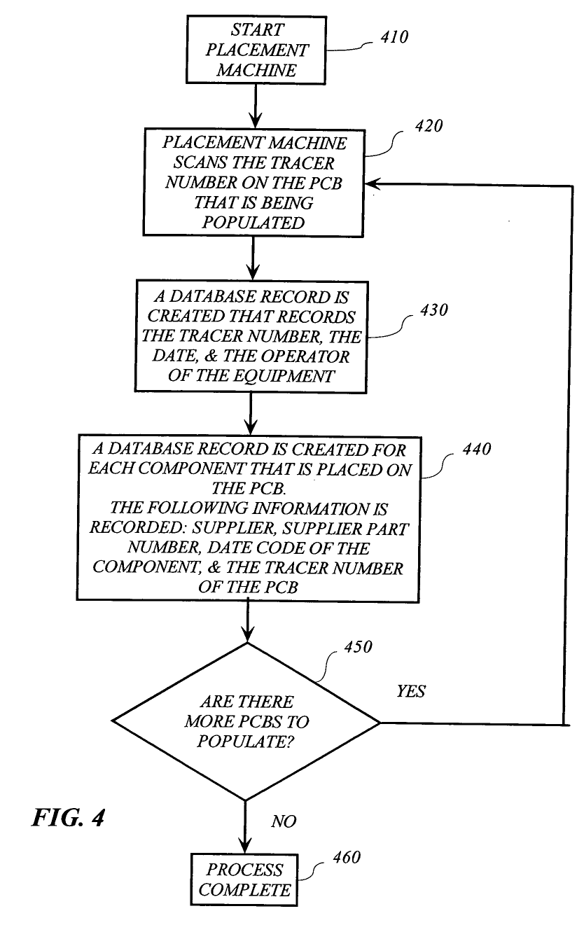

The embodiment of the method of FIG. 1 may be further described as component processes, as illustrated in FIGS. 2-4. FIG. 2 illustrates a method for providing identification for a component carrier or tube. FIG. 3 illustrates a method for loading a component carrier or tube in a placement machine. FIG. 4 illustrates a method for placing components from a component carrier or tube onto a printed circuit board, creating a database of information related to the component carrier and printed circuit board, generating a report from the database, and forwarding the report to an end user.

FIG. 2 illustrates an embodiment of a method for providing identification information associated with a tube. The components are received 110. Component information is entered into the database for the tube or component carrier 120. The information is manually entered by an operator. Barcodes are printed out and attached to the component carrier 130. Instead of printed out the barcodes, screen printing, etching, or another process may be used so long as the label is of sufficient durability and is readable by a scanner or other identification means. The component carrier or tube may be made identifiable through electronic means, including radio frequency identification tags. The components are then put in inventory 140.

FIG. 3 illustrates an embodiment of a method for loading components in the placement machine of the present invention. The placement machine load program is started 310. A specified component's carrier is loaded in the slot specified by the program in the placement machine 320. The program is stored in a memory coupled to a processor that may be housed within or on the placement machine or housed at a remote location. The barcode of the specified component's carrier is scanned 330. If the processor program determines that the desired or correct component has not been loaded 340, the error is corrected 350 and/or the operator may be alerted. For example, the error may be corrected by reloading the component carrier in the slot in question. If the desired component is determined to have been loaded 340, a determination is made as to whether there are more components to load 360. If there are, processing proceeds to step 320; otherwise, loading is completed and components are placed on the circuit board 370.

FIG. 4 illustrates an embodiment of a method for placing components onto a printed circuit board in the present invention. The placement machine is started 410. The placement machine scans the tracer number on the printed circuit board that is being populated 420. In the process, a database record is created that records the tracer number, the date, and the operator of the equipment 430. Additionally or alternatively, other information may be entered. A database record is created for each component that is placed on the printed circuit board 440. The following information is preferably recorded: customer's part number, contract manufacturer's part number, supplier's name, supplier's part number, date code of the component, and the tracer number of the printed circuit board 440. Then, a determination is made as to whether there are more printed circuit boards to populate 450. If there are, processing proceeds to step 420; otherwise, the process completes 460.

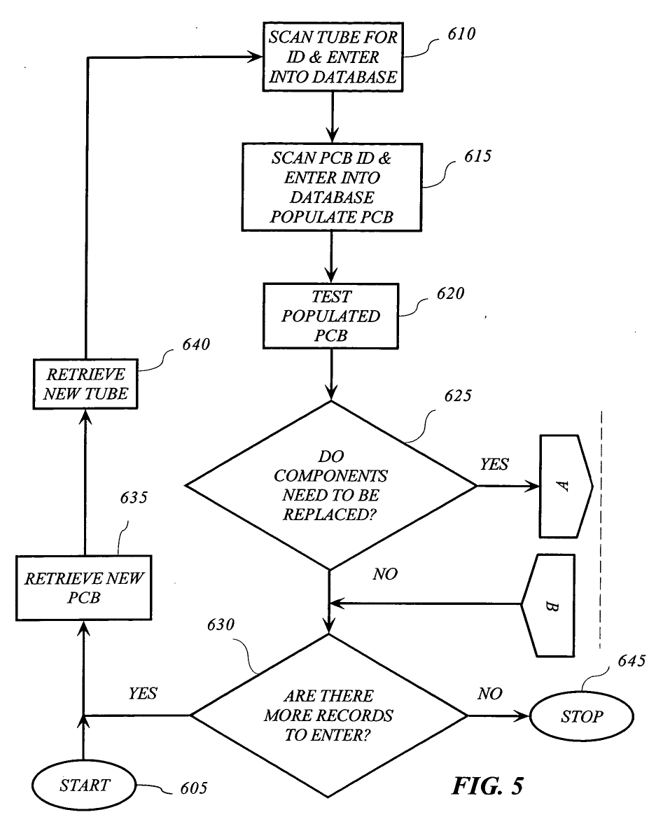

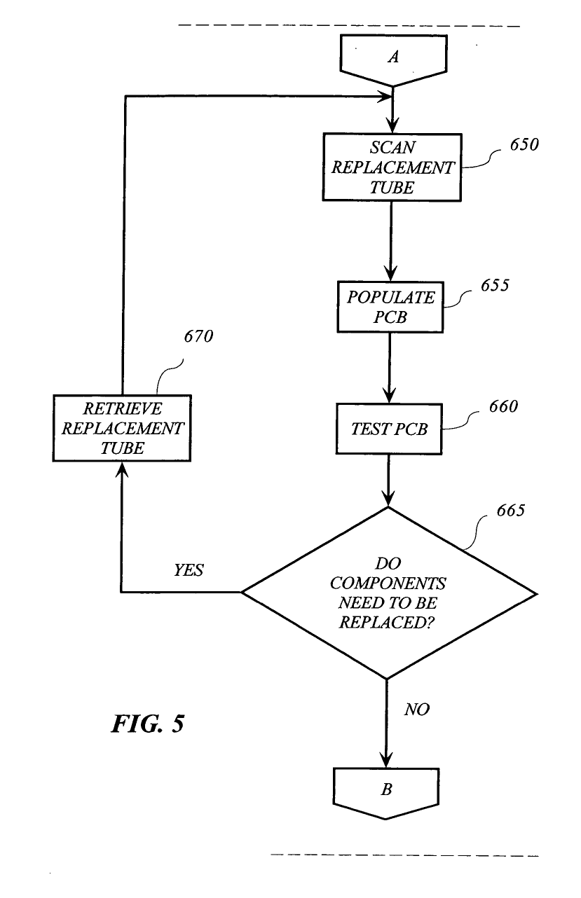

FIG. 5 illustrates a second or alternate embodiment to the general method of FIG. 1. This embodiment offers an on the fly solution to situations such as where a component from the component carrier or tube is faulty or is damaged beyond use in the placement process. A printed circuit board and a component carrier or tube are retrieved 635, 640. The tube is scanned for identification and entered in a database 610. The printed circuit board is scanned for identification information which is entered into a database 615. The printed circuit board is populated 615 and tested 620. If it is determined that components need to be replaced 625, a new replacement tube is scanned 650, the printed circuit board is populated 655 and tested 660. The process may continue in which case an optional determination is made as to whether replacement components need to be provided by another component carrier or tube 670 in which case another replacement tube is retrieved 670. After the components have been replaced, a determination is made as to whether there are more records to enter 630—such as when there are more printed circuit boards to populate. If there are not, processing stops 645. Otherwise, a new printed circuit board and, if needed, a new tube or component carrier are retrieved and appropriately mounted 635, 640.

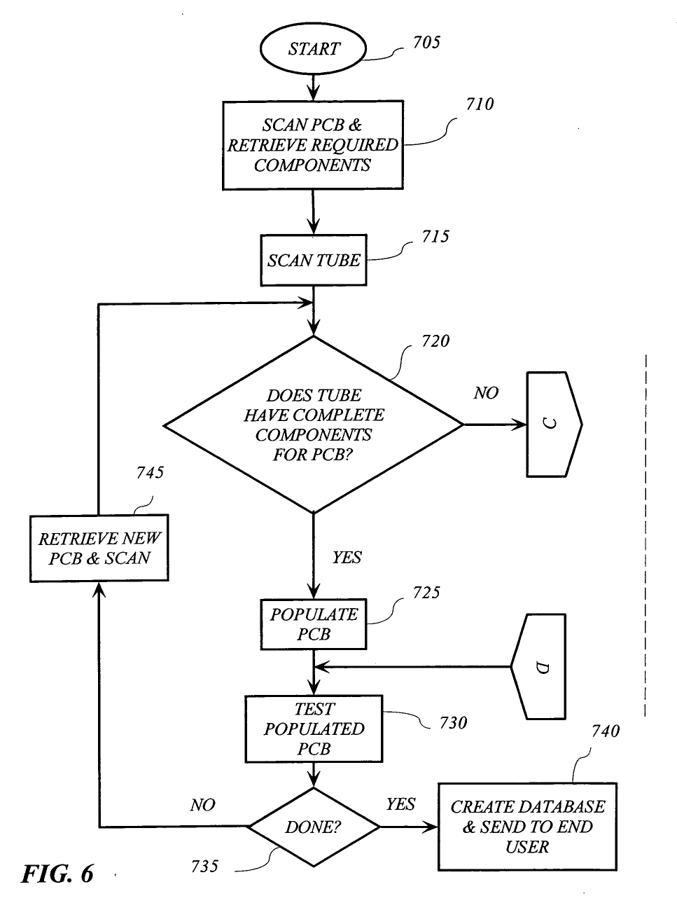

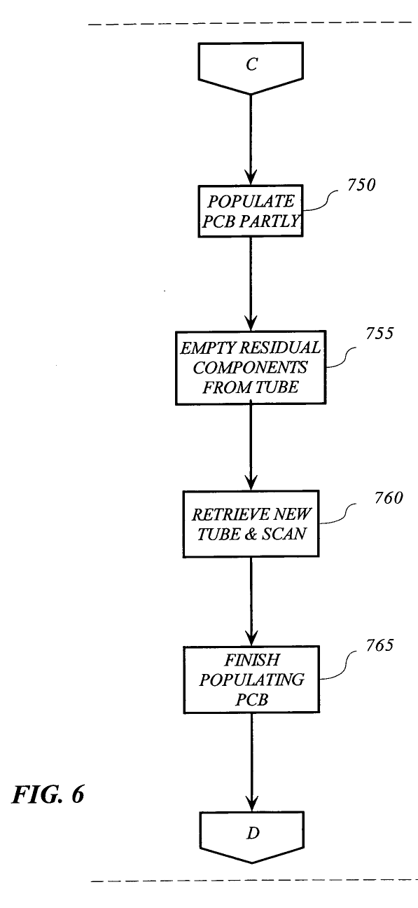

FIG. 6 illustrates a third embodiment of the method of the present invention in which a tube needs to be replaced while populating a printed circuit board. The printed circuit board is scanned 710. The necessary component carriers are retrieved, loaded, and scanned 715. If the tubes do not contain sufficient components for populating the printed circuit board 720, the printed circuit board is partly populated 750, a new tube is loaded and scanned 760, and populating continues 765. In some cases, such as when a batch of faulty components is located, it may be desirable to empty residual components from the tube or component carrier 755. If the tube is determined to have the complete components for populating the printed circuit board 720, the printed circuit board is populated 725. The populated printed circuit board may then optionally be tested 730. Test results may be added to the record entry for the printed circuit board concerned. If processing the printed circuit boards is completed 735, the information about the printed circuit board, tubes used, and optional test results will have been entered in a database from which a report is generated and sent to an end user 740. Otherwise, the next printed circuit board is retrieved 745.

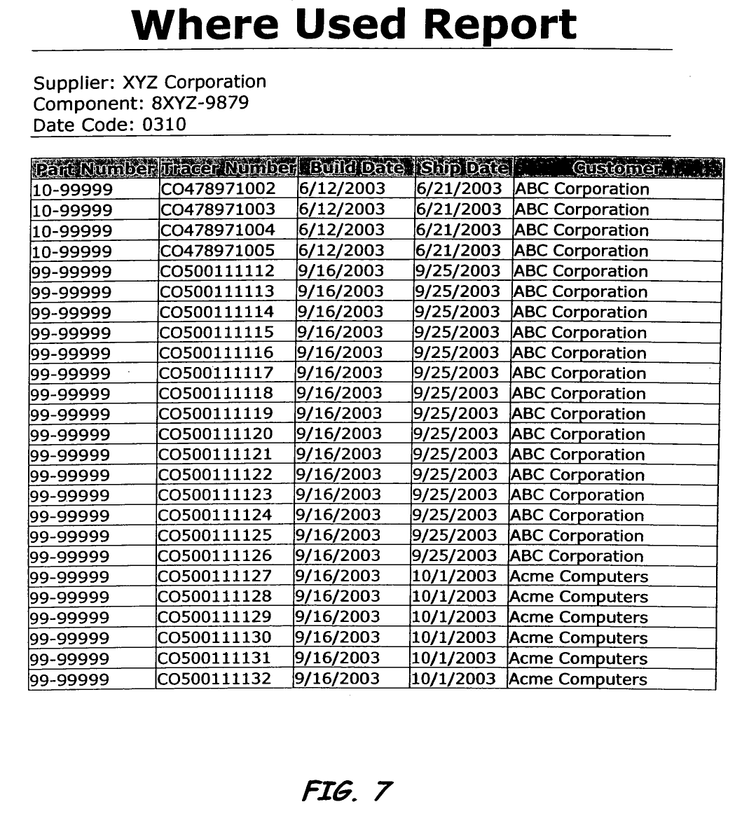

FIG. 7 illustrates an exemplary report generated by the method of the present invention. Here, the part number 10-9999 has been used for four printed circuit boards on build date Jun. 12, 2003, and ship date Jun. 21, 2003, for customer ABC Corporation. The other part number for component 8XYZ-9879, 99-99999, has been used for twenty one printed circuit boards for two different customers. The report may contain additional or alternate information, according to the needs and desires of the end user.

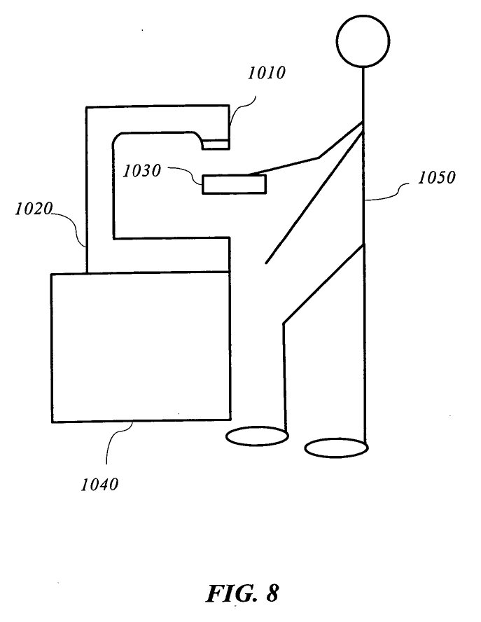

FIGS. 8-12 are directed to embodiments of the apparatus of the present invention. The apparatus for populating a traceable printed circuit board with traceable components includes a placement machine and may include a support, such as a cabinet or table. The placement machine preferably includes an identifiable unit loader for loading an identifiable unit, a circuit board support for holding a circuit board, a placement mechanism for populating the circuit board with a component corresponding to the identifiable unit, and a processor with an associated memory for storing information about the identifiable unit and the circuit board in a database. Although the identifiable unit may, in certain embodiments, be a component, preferably, the identifiable unit is a component carrier or tube. The identifiable unit contains readable identifying indicia. The readable identifying indicia may be optically or electronically readable. Preferably, the readably identifying indicia is a barcode. The printed circuit board also contains unique readable identifying indicia.

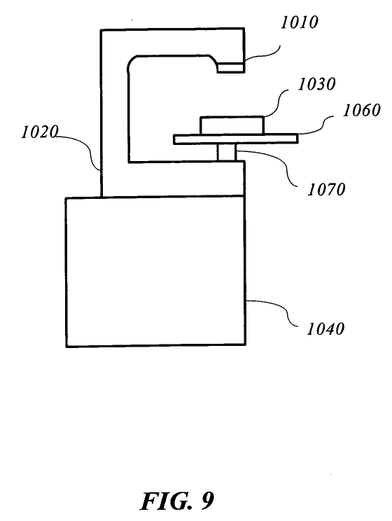

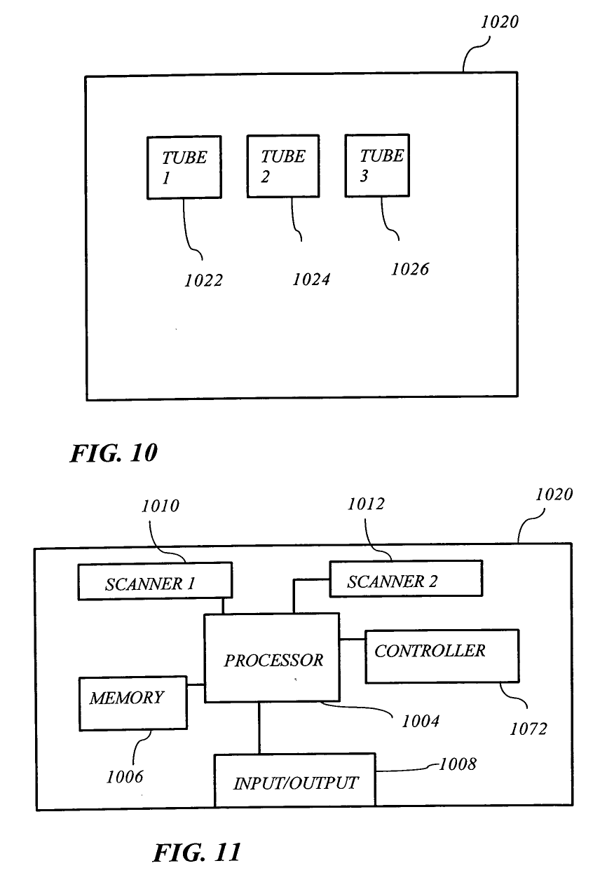

The placement machine of the present invention may be implemented with varying degrees of automation. FIG. 8 shows an embodiment of a placement machine 1020 in which an operator 1050 scans in identifying information from a component carrier or printed circuit board 1030 via a scanner 1010. The placement machine rests upon a support 1040, such as a supporting cabinet. FIG. 9 shows an embodiment in which the printed circuit board or component carrier 1030 may be transported by a conveyor system to a mounting plate 1060 of the placement machine 1020. Automated placement equipment may move the printed circuit board or component carrier from a conveyor belt. The mounting plate 1060 may secure a printed circuit board or component carrier 1030 through vacuum suction. A mechanical system of hydraulics, gears, rotary shafts, and the like may position the secured printed circuit board or component carrier 1030 up, down, forward, backward, sideways, and at a desired angle to enable the scanner 1010 to read the readable identifying indicia. FIG. 10 shows an embodiment in which the placement machine 1020 contains component carriers or tubes 1022, 1024, 1026 loaded into slots, bins, recesses, trays, and/or the like in the placement machine 1020.

The placement machine 1020 preferably contains or is otherwise associated with a processor 1004. The processor may be a microprocessor or other suitable computing and controlling device. FIG. 11 shows the processor 1004 housed within the placement machine 1020. The processor 1004 receives component carrier or printed circuit board identifying information from the scanner circuits 1010, 1012. One scanner circuit (i.e., scanner) 1010 may be dedicated to identifying a printed circuit board, while the other scanner 1012 is dedicated to identifying component carriers. In an embodiment, a separate scanner may be implemented in each load slot on the placement machine 1020. A memory 1006 associated with the processor 1004 may be used for storing the database as well as provide executable code for running the various processor operations. For example, the memory 1006 may contain battery backed random access memory to store the database information and a non-volatile read only memory to store executable program code. The processor 1004 may control the positioning operations for the mounting plate 1060, the feed operations from the component carrier to the placement machine 1020, and the placement operations in populating the printed circuit board. When prompted through the input/output interface 1008, the processor may prepare a report that is transmitted externally or provided through a display on the placement machine 1020. Alternatively, the processor may send raw data and/or may send a report on its own initiative according to predetermined criteria.

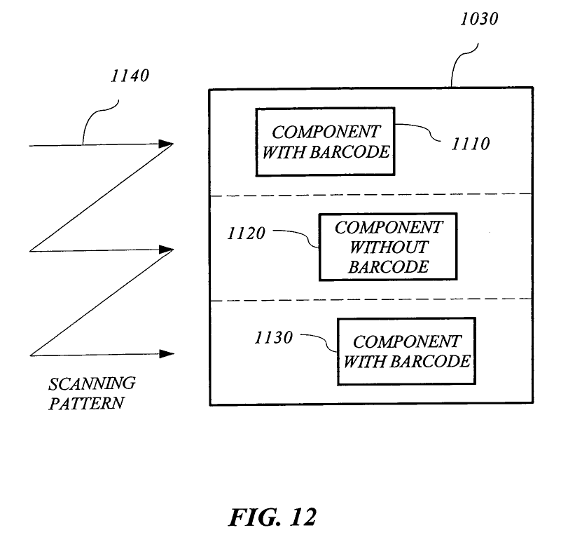

If automatic scanning of the printed circuit board is used, the mounting plate 1060 may be moved in a manner as shown in FIG. 12 by the scanning path arrows 1140. In this example, a first scan sweep would identify a first component with a barcode 1110, a second scan sweep would not identify second component 1120 because the second component 1120 does not have a barcode, and a third scan sweep would identify a third component with a barcode 1130. Alternatively, the scanner may be mounted in a moveable housing that could allow sweeping operations or the detecting beam of the scanner may be controlled so as to provide scanning sweeps. In this manner, a further check may be provided for the components used to populate a board. That is, the component carrier's information could be cross checked with the information scanned from the individual components populating a board even if only a portion of the components were identifiable by the scanner.

It is believed that the present invention and many of its attendant advantages will be understood by the forgoing description. It is also believed that it will be apparent that various changes may be made in the form, construction and arrangement of the components thereof without departing from the scope and spirit of the invention or without sacrificing all of its material advantages, the form hereinbefore described being merely an explanatory embodiment thereof. It is the intention of the following claims to encompass and include such changes.

1. A method for providing a traceable populated printed circuit board, comprising:
loading an identifiable unit in a placement machine;
holding and identifying a circuit board by the placement machine;
populating the circuit board with a component corresponding to the identifiable unit; and
creating a database associating information about the identifiable unit with information about the circuit board.

2. The method of claim 1, wherein the identifiable unit is a component.

3. The method of claim 1, wherein the identifiable unit is a component carrier.

4. The method of claim 1, wherein the identifiable unit is a tube.

5. The method of claim 4, wherein the tube stores multiple components including the component corresponding to the identifiable unit.

6. The method of claim 1, further comprising identifying the identifiable unit by the placement machine.

7. The method of claim 6, wherein identifying the identifiable unit by the placement machine occurs before loading the identifiable unit in the placement machine.

8. The method of claim 6, wherein identifying the identifiable unit by the placement machine occurs after loading the identifiable unit in the placement machine.

9. The method of claim 6, wherein identifying the identifiable unit by the placement machine occurs during loading the identifiable unit in the placement machine.

10. The method of claim 1, further comprising generating a report from the database.

11. The method of claim 10, further comprising sending the report to an end user.

12. The method of claim 11, wherein the report is sent over the world wide web.

13. The method of claim 1, the circuit board aforementioned being a first circuit board, further comprising, after populating the first circuit board, retrieving a second circuit board to be populated from the identifiable unit.

14. An apparatus for populating a traceable printed circuit board with traceable components, comprising:
a placement machine, comprising:
an identifiable unit loader for loading an identifiable unit;
a circuit board support for holding a circuit board;
a placement mechanism for populating the circuit board with a component corresponding to the identifiable unit; and
a processor with an associated memory for storing information about the identifiable unit and the circuit board in a database.

15. The apparatus of claim 14, wherein the component is the identifiable unit.

16. The apparatus of claim 14, wherein the component is a component carrier.

17. The apparatus of claim 14, wherein the component is a tube.

18. The apparatus of claim 14, wherein the identifiable unit is identified by a bar code located on the identifiable unit.

19. The apparatus of claim 18, wherein the circuit board is identified by a bar code located on the circuit board.

20. The apparatus of claim 14, wherein the circuit board is identified by a bar code located on the circuit board.

21. The apparatus of claim 14, wherein the placement machine includes a scanner that identifies the identifiable unit.

22. The apparatus of claim 21, wherein the scanner aforementioned is a first scanner, the placement machine including a second scanner for identifying the circuit board.

23. The apparatus of claim 21, wherein the scanner also identifies the circuit board.

24. The apparatus of claim 21, wherein at least some of the information stored about the identifiable unit is provided by the scanner.

25. An apparatus for populating a traceable printed circuit board with traceable components, comprising:
means for receiving and identifying an identifiable unit;
means for identifying a circuit board;
means for placing a component corresponding to the identifiable unit onto the circuit board; and
means for creating a database containing information about the identified identifiable unit and the identified circuit board.

26. The apparatus of claim 25, further comprising means for mounting and moving the circuit board.

27. The apparatus of claim 25, further comprising means for generating a report from the database.

28. The apparatus of claim 27, further comprising displaying the report on a screen on the means for placing a component.

29. The apparatus of claim 27, further comprising means for transmitting the report to an end user.

30. The apparatus of claim 25, wherein the apparatus is a placement machine.

31. A method for providing a traceable populated printed circuit board, comprising:
loading a specified component's carrier in a placement machine slot specified by executable code associated with a placement machine;
scanning a barcode of the specified component's carrier;
if the barcode is correct, then determining if there are more component carriers to load;
if there are no more component carriers to load, then scanning a tracer number of a circuit board to be populated; and
creating a database record including information associated with the specified component's carrier and information associated with the circuit board.

32. The method of claim 31, further comprising receiving components and entering information about the components in a database prior to loading a specified component's carrier in the placement machine slot.

33. The method of claim 32, further comprising attaching bar codes to the components and putting the components in inventory after entering information about the components in a database and before loading a specified component's carrier in the placement machine slot.

34. The method of claim 31, further comprising, if the barcode is not correct, providing a component carrier with a correct barcode.

35. The method of claim 31, further comprising, if there are more component carriers to load, then loading these component carriers.
